(19) United States
(12) Patent Application Publication
(10) Pub. No.: US 2013/0005279 A1
(43) Pub. Date: Jan. 3, 2013

(54) SEMICONDUCTOR SWITCH AND WIRELESS DEVICE

(75) Inventors: Toshifumi ISHIMORI, Kanagawa-ken (JP); Toshiki Seshita, Kanagawa-ken (JP)

(73) Assignee: KABUSHIKI KAISHA TOSHIBA, Tokyo (JP)

(21) Appl. No.: 13/422,559

(22) Filed: Mar. 16, 2012

(30) Foreign Application Priority Data
Jul. 1, 2011 (JP) 2011-147415

(51) Int. Cl. H04B 1/44; H03K 17/687; H03K 17/56

(52) U.S. Cl. 455/83; 327/419; 327/434

(57) ABSTRACT

According to one embodiment, a semiconductor switch includes a switch section, a driver, and a power supply. The switch section switches a connection between a common terminal and a plurality of radio-frequency terminals. The driver outputs a control signal to the switch section based on a terminal switching signal. The power supply generates a first potential based on a reference potential varying in accordance with temperature and outputs the first potential to the driver.

### CROSS-REFERENCE TO RELATED APPLICATIONS

This application is based upon and claims the benefit of priority from the prior Japanese Patent Application No. 2011-147415, filed on Jul. 1, 2011; the entire contents of which are incorporated herein by reference.

### FIELD

Embodiments described herein relate generally to a semiconductor switch and a wireless device.

### BACKGROUND

A semiconductor switch which switches circuits on and off can be used in a variety of electronic devices. For example, in the radio-frequency circuits of mobile phones, the transmitting circuit and receiving circuit are arranged to selectively connect to a shared antenna via a radio-frequency switch circuit. In the switch devices of such radio-frequency switch circuits, MOSFET (Metal Oxide Semiconductor Field Effect Transistor) formed on SOI (Silicon On Insulator) substrates are used.

When the FET is used as the switch device, radio-frequency characteristics of the FET such as distortion depend on the voltage and temperature that switch the FET on or off, and so it is necessary to apply a suitable voltage.

### BRIEF DESCRIPTION OF THE DRAWINGS

FIG. 1 is a block diagram illustrating a configuration of a semiconductor switch according to a first embodiment;

FIG. 2 is a circuit diagram illustrating a configuration of a switch section of the semiconductor switch;

FIG. 3 is a characteristics plot illustrating a dependency of second-order intermodulation distortion IMD2 in the switch section on a first potential Vp;

FIG. 4 is a characteristics plot illustrating temperature dependence of an insertion loss and a second-order intermodulation distortion IMD2 in the switch section;

FIG. 5 is a circuit diagram illustrating a configuration of a power supply of the semiconductor switch;

FIG. 6 is a circuit diagram illustrating a configuration of a clamper of the semiconductor switch;

FIG. 7 is a characteristics plot illustrating temperature dependence of the insertion loss and the second-order intermodulation distortion IMD2 of the semiconductor switch;

FIG. 8 is circuit diagram illustrating another configuration of a clamper of the semiconductor switch;

FIG. 9 is a circuit diagram illustrating a configuration of a semiconductor switch according to a second embodiment;

FIG. 10 is a circuit diagram illustrating a configuration of an interface circuit and a driver of the semiconductor switch;

FIG. 11 is a circuit diagram illustrating a configuration of a clamper of the semiconductor switch; and

FIG. 12 is a block diagram illustrating a configuration of a wireless device according to a third embodiment.

### DETAILED DESCRIPTION

In general, according to one embodiment, according to one embodiment, a semiconductor switch includes a switch section, a driver, and a power supply. The switch section switches a connection between a common terminal and a plurality of radio-frequency terminals. The driver outputs a control signal to the switch section based on a terminal switching signal. The power supply generates a first potential based on a reference potential varying in accordance with temperature and outputs the first potential to the driver.

Hereinbelow, embodiments are described with reference to the drawings. In the following description, identical components are marked with the same reference numerals, and a description of components once described is omitted as appropriate. The embodiments described below can be appropriately combined.

First, a first embodiment is described.

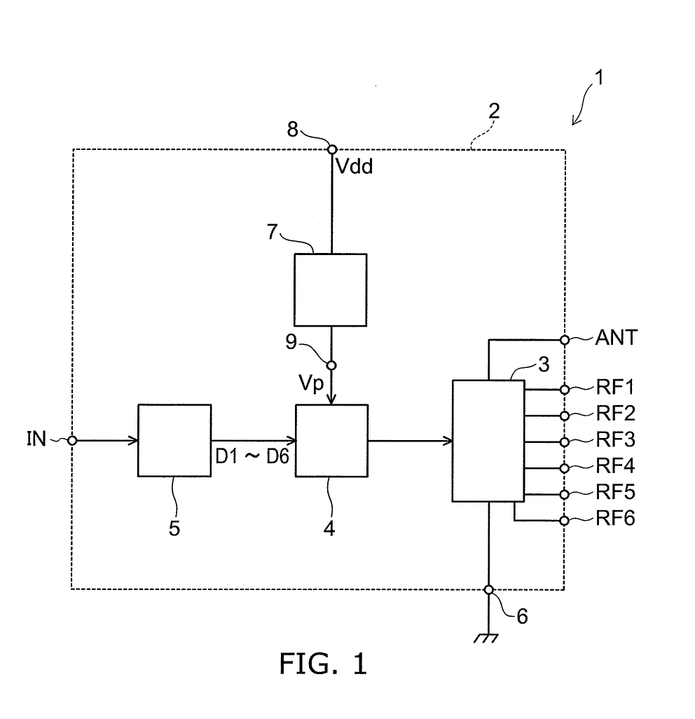

FIG. 1 is a block diagram illustrating a configuration of a semiconductor switch according to the first embodiment.

A semiconductor switch 1 includes, a switch section 3, a driver 4 that outputs a control signal to the switch section 3, an interface circuit 5 that decodes a terminal switching signal IN to the driver 4 and a power supply 7 that generates a first potential that is a potential of the control signal. The semiconductor switch 1 is an SP6T (Single-Pole 6-Throw) switch that switches the connection between the common terminal ANT and the radio-frequency terminals RF1 to RF6 in response to the terminal switching signal IN.

The switch section 3 switches connection between the terminals of a common terminal ANT and a plurality of radio-frequency terminals RF1 to RF6 according to a control signal outputted from the driver 4. Further, the switch section 3 is, for example, configured using an SOI-structure MOSFET provided on an SOI substrate (portion surrounded by broken line 2). The switch section 3 can also be used in multimode and multiband wireless devices having multiple ports. Although, in the following, the configuration of the SP6T switch is described as an example, switches of other configurations can be applied in a similar fashion, and any wPkT (where w is a natural number, and k is a natural number not less than 2) switch can be configured.

The driver 4 generates a control signal which switches the connections of the switch section 3 according to the terminal switching signal IN inputted via the interface circuit 5. The driver 4 is supplied with a first potential Vp. Here, the first potential Vp is a potential of the high level of the control signal and is the potential to which the terminals in the switch section 3 are connected. The first potential Vp is a potential which, in the switch section 3 configured using MOSFETs, switches on each FET when applied to the corresponding FET gate and sets the on-resistance of the FET to a sufficiently low value.

The interface circuit 5 decodes the terminal switching signal IN inputted from an external portion and outputs decoded signals D1 to D6 to the driver 4. The terminal switching signal IN inputted to the interface circuit 5 may be either of parallel data and serial data.

The power supply 7 is supplied with positive power supply potential Vdd via a power supply terminal 8 and generates the first potential Vp as a control signal potential. Further, a value of the first potential Vp is generated based on a reference potential that changes according to temperature and is thus temperature controlled so as to have positive or negative temperature characteristics according to a temperature dependence of insertion loss and distortion characteristics of the switch section 3. The first potential Vp is outputted to driver 4 and improves the radio-frequency characteristics of the switch section 3 by compensating for the temperature dependence of the radio-frequency distortion of the FETs therein.

Next, the parts are described in detail.

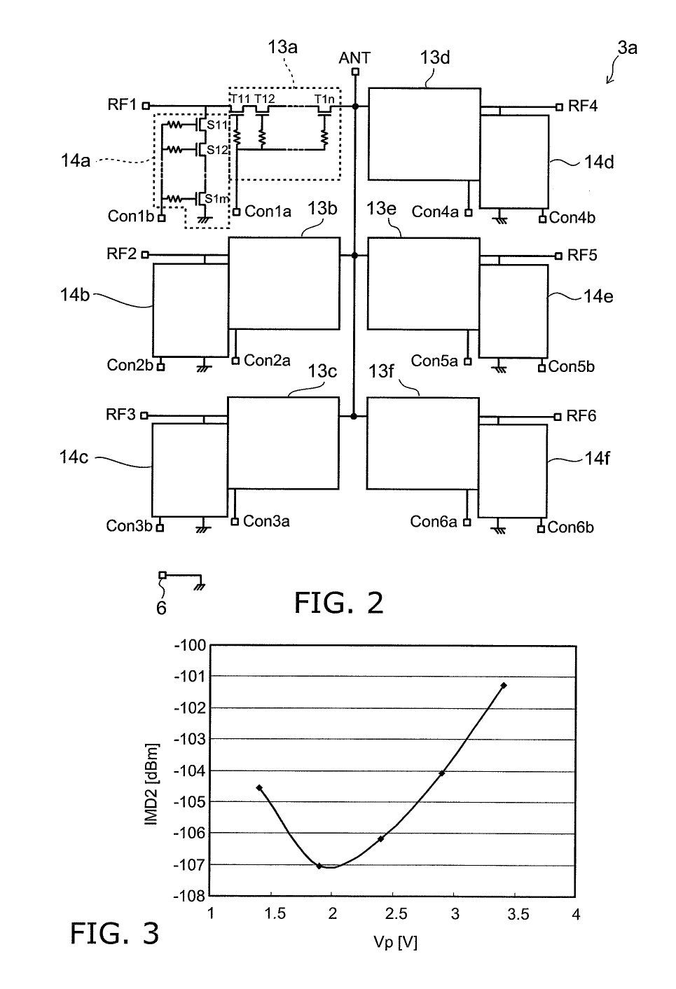

FIG. 2 is a circuit diagram illustrating a configuration of a switch section of the semiconductor switch.

As shown in FIG. 2, a switch section 3a is an SP6T switch. A first switch device (portion surrounded by the broken line 13a) is connected between common terminal ANT and the radio-frequency terminal RF1. Further, first switch devices 13b, 13c, 13d, 13e and 13f are each connected between the common terminal ANT and a corresponding one of the radio-frequency terminals RF2, RF3, RF4, RF5 and RF6. Switching on each of first switch devices 13a, 13b, 13c, 13d, 13e and 13f allows conduction between the common terminal ANT and the corresponding radio-frequency terminals RF1, RF2, RF3, RF4, RF5 and RF6.

The first switch device 13a includes an n-stage (where n is a natural number) through FETs T11, T12, . . . , T1n connected in series. A control signal Conia is inputted via the resistors for radio-frequency leakage protection to the gates of through FETs T11, T12, . . . , T1n. The first switch devices 13b, 13c, 13d, 13e and 13f each have the same configuration as the first switch device 13a. Each of the control signals Con2a, Con3a, Con4a, Con5a and Con6a are inputted to a corresponding one of the first switch devices 13b, 13c, 13d, 13e and 13f, respectively.

A second switch device is connected between the radio-frequency terminal RF1 and a ground terminal 6 (portion surrounded by the broken line 14a). Each of the second switch devices 14b, 14c, 14d, 14e and 14f is also connected between a corresponding one of the radio-frequency terminals RF2, RF3, RF4, RF5 and RF6 and the ground terminal 6. The second switch devices 14a, 14b, 14c, 14d, 14e and 14f improve isolation between the radio-frequency terminals RF1, RF2, RF3, RF4, RF5 and RF6 by allowing leakage currents flowing in each of the radio-frequency terminals RF1, RF2, RF3, RF4, RF5 and RF6 to escape to ground GND via the ground terminal 6 when the corresponding first switch devices 13a, 13b, 13c, 13d, 13e and 13f are off.

The second switch device 14a includes an m-stage (where m is a natural number) shunt FETs S11, S12, . . . , S1m connected in series. A control signal Conib is inputted to the gates of the shunt FETs S11, S12, . . . , S1m via resistors for radio-frequency leakage protection. The second switch devices 14b, 14c, 14d, 14e and 14f each have the same configuration as the second switch device 14a. Control signals Con2b, Con3b, Con4b, Con5b and Con6b are inputted to the second switch devices 14b, 14c, 14d, 14e and 14f, respectively.

For example, with the following control settings, there will be conduction between the radio-frequency terminal RF1 and the common terminal ANT. This is that the first switch device 13a between the radio-frequency terminal RF1 and the common terminal ANT is ON, and the second switch device 14a between the radio-frequency terminal RF1 and the ground terminal 6 is OFF. In other words, the through FETs T11, T12, . . . , T1n of the first switch device 13a are all ON, and the shunt FETs S11, S12, . . . , S1m of the second switch device 14a are all OFF.

At this time, the first switch devices 13b, 13c, 13d, 13e and 13f between the other radio-frequency terminals RF2, RF3, RF4, RF5 and RF6 and the common terminal ANT are all OFF, and the second switch devices 14b, 14c, 14d, 14e and 14f between the other radio-frequency terminals RF2, RF3, RF4, RF5 and RF6 and the ground terminal 6 are all ON. Thus, the through FETs of the first switch devices 13b, 13c, 13d, 13e and 13f are all OFF, and the shunt FETs of the second switch devices 14b, 14c, 14d, 14e and 14f are all ON.

In the case described above, the control signal Conga is set to the first potential Vp, the control signals Con2b, Con3b, Con4b, Con5b and Con6b to the first potential Vp, the control signal Con1b to the second potential Vn, and the control signals Con2a, Con3a, Con4a, Con5a and Con6a to the second potential Vn.

Here, the second potential Vn is the potential of the low level of the control signal, which is a potential which cuts off the terminals in the switch section 3. For example, the second potential Vn turns the FETs OFF when applied to the gates of the FETs in the switch section 3 and is sufficient to keep the FETs in the OFF state even when a radio-frequency signal is superimposed. For example, the second potential Vn may be a ground potential of 0 V or a negative potential.

If the second potential Vn is higher than the predetermined potential, maximum permitted input power will be reduced and distortion (off-distortion) generated by the FET in the cutoff state at a rated input increases.

Further, as described above, the first potential Vp puts the FETs in a conducting state and keeps the on-resistance at a sufficiently low value. The second potential Vn is a potential that causes the FETs to enter the cutoff state and allows the cutoff state to be safely maintained even when an RF signal is superimposed.

When the first potential Vp drops below a predetermined potential (such as 2 V), the on-resistance of the conduction state FET increases. Thus, insertion loss, which is power loss when input power is transferred to the output side, worsens, and distortion (on-distortion) generated by the FET in the conduction state increases.

FIG. 3 is a characteristics plot illustrating a dependency of second-order intermodulation distortion IMD2 in the switch section on the first potential Vp.

FIG. 3 shows the dependency of second-order intermodulation distortion IMD2, calculated from measurements taken when testing the switch section, on the first potential Vp. As the first potential Vp is reduced below 3.5 V, the second-order intermodulation distortion IMD2 also reduces. When the first potential is reduced further, the second-order intermodulation distortion IMD2 to increase and the characteristics deteriorate.

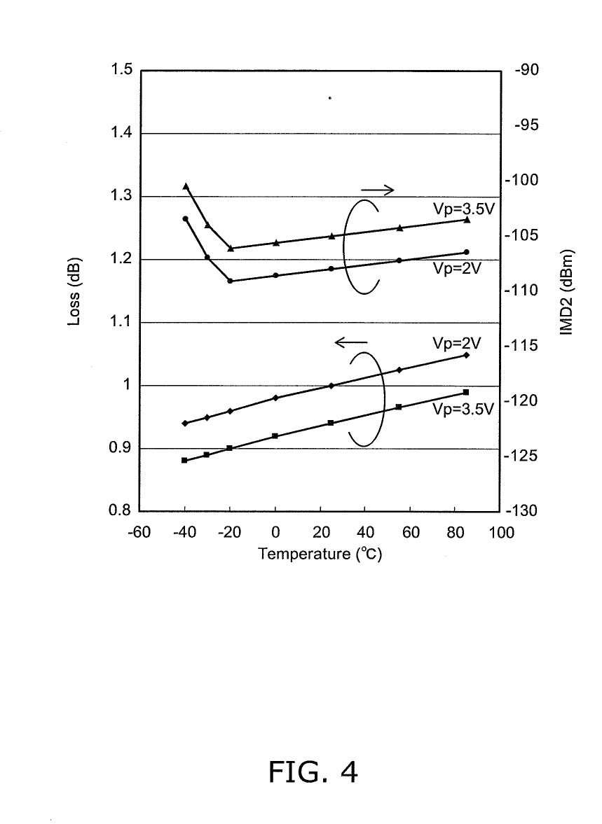

FIG. 4 is a characteristics plot illustrating temperature dependence of an insertion loss and an second-order intermodulation distortion IMD2 in the switch section.

FIG. 4 shows actual measurements of the temperature-dependence of insertion loss and second-order intermodulation distortion when the first potential Vp of a fixed value is supplied to the tested switch section.

When the first potential Vp is a fixed value, the characteristics are such that insertion loss decreases monotonically as temperature decreases. The second-order intermodulation distortion IMD2 decreases monotonically as temperature decrease to −20° C. If the temperature decreases further, the characteristics are such that the second-order intermodulation distortion IMD2 increases. For example, when the first potential Vp is 3.5 V, the value of second-order intermodulation distortion IMD2 at a temperature of −40° C. deteriorates approximately 4.5 dB from the value at normal temperature (25° C.).

On the other hand, the insertion loss increases monotonically with temperature in the −40° C. to 85° C. range. For example, when the first potential Vp is 3.5 V, the value of the insertion loss at a temperature of 85° C. deteriorates approximately 0.05 dB from the value at normal temperature. Hence, to obtain a favorable insertion loss, it is necessary to increase the first potential Vp (to 3.5 V, for example).

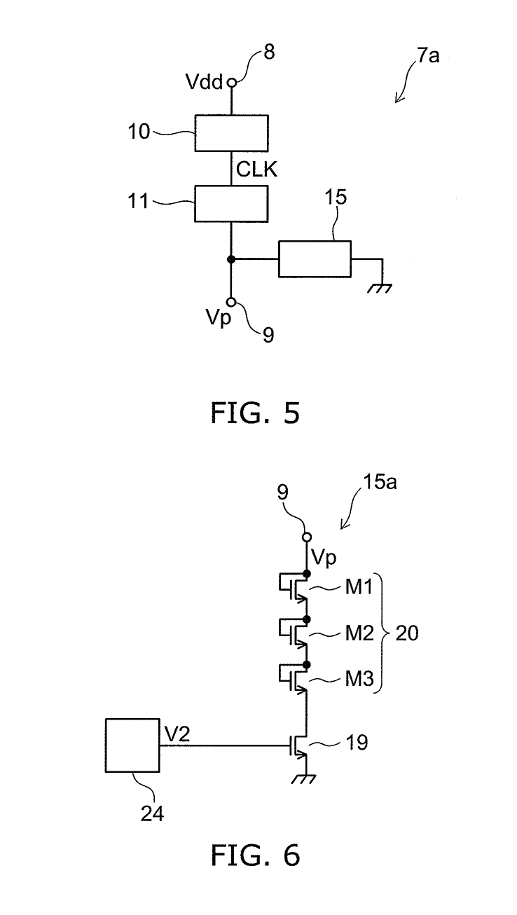

FIG. 5 is a circuit diagram illustrating a configuration of a power supply of the semiconductor switch.

A power supply 7a includes an oscillator circuit 10, a charge pump 11 and a clamper 15. The oscillator circuit 10 is supplied with a power supply potential Vdd by a power supply terminal 8 and generates a clock signal CLK. A charge pump 11 receives input of the clock signal CLK and generates a first potential Vp a high-potential power supply terminal 9.

The clamper 15 is connected between the high-potential power supply terminal 9 and ground and clamps the first potential Vp. The potential to be clamped is temperature controlled, and the clamper 15 sets a desired value for temperature characteristics of the first potential Vp by clamping the first potential Vp.

FIG. 6 is a circuit diagram illustrating a configuration of a clamper of the semiconductor switch.

FIG. 6 illustrates a configuration of a clamper that works to clamp first potential Vp so as to have a positive temperature characteristics.

A clamper 15a includes a first transistor 19 and a second transistor 20 that clamp the first potential Vp at the high-potential power supply terminal 9. Also, a temperature detection circuit 24 controls the first transistor 19 to be ON or OFF according to temperature.

The first transistor 19 and the second transistor 20 are connected in series between the high-potential power supply terminal 9 and ground. The first transistor 19 is configured from an N-channel MOSFET (hereinafter referred to an NMOS), and has a source connected to ground and a drain connected to the second transistor 20. A gate of the first transistor 19 is connected to an output of the temperature detection circuit 24.

The second transistor 20 is configured from three diode-connected NMOS M1, M2 and M3. Although FIG. 6 illustrates a configuration in which the first potential Vp is clamped by three NMOS, the number can be freely selected according to the value of the first potential Vp.

The temperature detection circuit 24 detects a temperature that causes the first potential Vp to change. The temperature detection circuit 24 outputs, as a reference potential, a potential V2 which is at the low level when the ambient temperature is higher than a normal temperature (25° C.) and at the high level when the ambient temperature is lower than the normal temperature (25° C., for example). For instance, the temperature characteristics of the diodes, resistors and the like can be configured using known devices.

When the ambient temperature is higher than the normal temperature, a gate potential of the first transistor 19 goes to the low level and the first transistor 19 is switched OFF. The connection of the second transistor 20 to ground is thereby cut off. The clamper 15a enters a state of non-operation, and the first potential Vp rises to an output potential of the charge pump 11. When the first transistor 19 is OFF, to suppress any rise in the first potential Vp, a clamp device with a higher clamp potential than the second transistor 20, such as a diode-connected transistor, may be connected between the high-potential power supply terminal and ground.

Further, when the ambient temperature is lower than the normal temperature, the gate potential of the first transistor 19 goes to the high level, and the first transistor 19 switches ON. The second transistor 20 is thus conducts between the high-potential power supply terminal 9 and ground via the first transistor 19. The clamper 15a clamps the first potential Vp to a clamp potential of the second transistor 20.

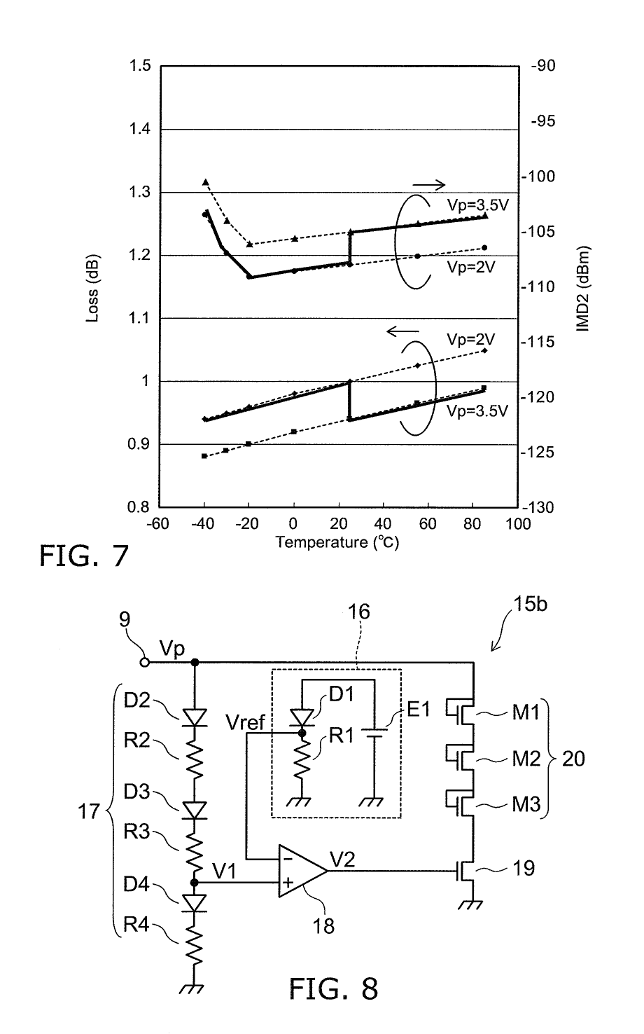

FIG. 7 is a characteristics plot illustrating temperature dependence of the insertion loss and the second-order intermodulation distortion IMD2 of the semiconductor switch.

FIG. 7 illustrates the characteristics of the semiconductor switch when the clamper 15a is used in the power supply 7a. The characteristics of the switch section 3 are the same as those of FIG. 4.

The power supply 7a supplies the first potential Vp to the switch section 3, such that there is a temperature controlled change at the normal temperature of 25° C. The first potential Vp changes in proximity to the normal temperature, going to 3.5 V when the temperature is higher than the normal temperature, and to 2 V when the temperature is lower than normal temperature.

At temperatures lower than the normal temperature, the second-order intermodulation distortion IMD2 characteristics is lowered to below the level seen when first potential Vp is 3.5 V by reducing the first potential Vp to 2 V. For example, when the temperature is −40° C., setting the first potential Vp being to 2 V improves the value of the second-order intermodulation distortion IMD2 by 3 dB.

Reducing the first potential Vp worsens the insertion loss. However, because insertion loss is temperature dependent and has favorable characteristics at low temperature, insertion loss does not deteriorate significantly. For example, the value of the insertion loss at −40° C. is approximately the same as the value at normal temperature when the first potential Vp is 3.5 V.

In both FIG. 4 and FIG. 7, when the first potential Vp drops to 2 V, the second-order intermodulation distortion IMD2 characteristics become favorable. However, FIG. 4 and FIG. 7 are no more than examples of characteristics of the switch section, and dependencies may differ according to a manufacturing method of the SOI substrate 2 and the circuit configuration of the switch section 3. For example, when the first potential Vp is high, the second-order intermodulation distortion IMD2 may be favorable even at low temperature.

Hence, although a configuration was used such that the first potential Vp is set low at low temperature to ensure favorable second-order intermodulation distortion IMD2 characteristics in FIG. 7, it may be preferable to design with a configuration that causes the first potential Vp to rise at low temperature or the like, so that the first potential Vp is optimal for the characteristics of the switch device being manufactured.

Also, for the example of characteristics shown in FIG. 7, the detection accuracy of the temperature detection circuit 24 need not be high and may be between several ° C. and several tens of ° C.

Also, although the clamper 15a is configured so that the temperature control operates to change first potential Vp in proximity to the normal temperature, a temperature control configuration which makes continuous finer adjustments to the first potential Vp is also possible.

FIG. 8 is circuit diagram illustrating another configuration of a clamper of the semiconductor switch.

FIG. 8 illustrates a configuration of a clamper which clamps so that the first potential Vp has a positive temperature characteristic

A clamper 15b includes a reference potential generator (portion surrounded by a broken line) 16. The reference potential generator 16 is configured by dividing the output of a voltage source circuit E1, which is temperature-compensated with a temperature coefficient 0, using a diode (pn junction diode) D1 and a resistor R1, and generates a reference potential Vref that is varied to provide the positive temperature characteristic. At low temperature, the forward voltage of the diode D1 increases, causing the reference potential Vref to drop. The voltage source circuit E1 is, for example, configured using a band gap voltage source circuit or the like.

In a detection circuit 17, diodes D2, D3 and D4, and resistors R2, R3 and R4 are connect in series between the high-potential power supply terminal 9 and ground. A potential V1 that results from dividing the first potential Vp is generated on the high potential side of the series-connected diode 4 and resistor R4. Note also that, although FIG. 7 illustrates a configuration having three diodes and three resistors, the number can be freely selected according to the characteristics of the MOSFETs of the switch section 3.

The difference between potential V1, which results from dividing the first potential Vp and the reference potential Vref, is amplified by an operational amplifier (amplifier) 18 and inputted to the gate of the first transistor 19, which is configured using NMOS. The first transistor 19 is controlled by a potential V2 that results from amplifying the difference between the potential V1 and the reference potential Vref, and generates a current in accordance with the potential V2.

The second transistor 20 is connected in series with the first transistor 19 and clamps the first potential Vp using the potential that changes in accordance with the current generated by the first transistor 19. The second transistor 20 is configured using three diode-connected NMOS M1, M2 and M3. Although the clamping configuration illustrated in FIG. 7 uses three NMOS, the number may be freely selected according to the value of the first potential Vp.

As described above, a detection circuit 17 divides the first potential Vp supplied via the high-potential power supply terminal 9 and supplies the resulting potential V1 to the non-inverting input terminal (+) of the operational amplifier 18. The reference potential generator 16 generates the reference potential Vref that varies according to temperature and supplies the generated reference potential Vref to the inverting input terminal (−) of the operational amplifier 18. Here, when the first potential Vp goes high, the detection circuit 17 generates a correspondingly high potential V1. When the potential V1 exceeds the reference potential Vref, the operational amplifier 18 sets the output potential V2 high.

The operational amplifier 18 outputs the output potential V2 according to the result of a comparison of the potential V1 with the reference potential Vref. As illustrated in FIG. 7, if the reference potential Vref drops at low temperature, the operational amplifier 18 outputs an output potential V2 which is high at low temperature. At high temperature, the reference potential Vref is high, and so the operation is reversed, meaning that the operational amplifier 18 outputs an output potential V2 which is low.

For example, when the output potential V2 is high and a gate-source voltage of the first transistor 19 is higher than a threshold value voltage, the first transistor 19 goes into an ON state. The first potential Vp is clamped at a potential determined by the second transistor 20 with the multistage connection using the NMOS M1, M2 and M3.

When the potential V1 goes low, the first transistor 19 is reliably prevented from going into the ON state. Hence, the second transistor 20 clamps to a first potential Vp which is higher than when the first transistor 19 is in the ON state.

When the output potential V2 goes low and the gate-source voltage of the first transistor 19 reaches a voltage significantly lower than the threshold value voltage, the first transistor 19 enters the fully OFF state. Hence, current does not flow in the second transistor 20, and the second transistor 20 is in a state similar to being unconnected. Since the first potential Vp becomes the unaltered output of the charge pump 11, the first potential Vp goes to the highest state.

Accordingly, the value of the first potential Vp is fed back through the first transistor 19 and the second transistor 20 as negative feedback. Thus, the first potential Vp is controlled according to temperature, dropping when the temperature is low and rising when the temperature is high.

When the clamper 15b is used, the power supply 7a performs temperature control to change the value of the first potential Vp according to the reference potential Vref. Thus, if the power supply 7a is used as a switch circuit, the deterioration of second-order intermodulation distortion IMD2 at low temperature can be improved. As described above, the insertion loss is worsened by the reduction of the first potential Vp. However, because the insertion loss is temperature dependent and has favorable properties at low temperatures, there is no large deterioration.

Thus, in the semiconductor switch according to the first embodiment, the first potential Vp generated by the power supply is temperature controlled according to the temperature dependence of radio-frequency distortion in the switch section. As a result, increases in insertion loss can be suppressed, increases in the second-order intermodulation distortion IMD2 due to temperature can be suppressed, and the radio-frequency characteristics can be improved.

Next a second embodiment will be described.

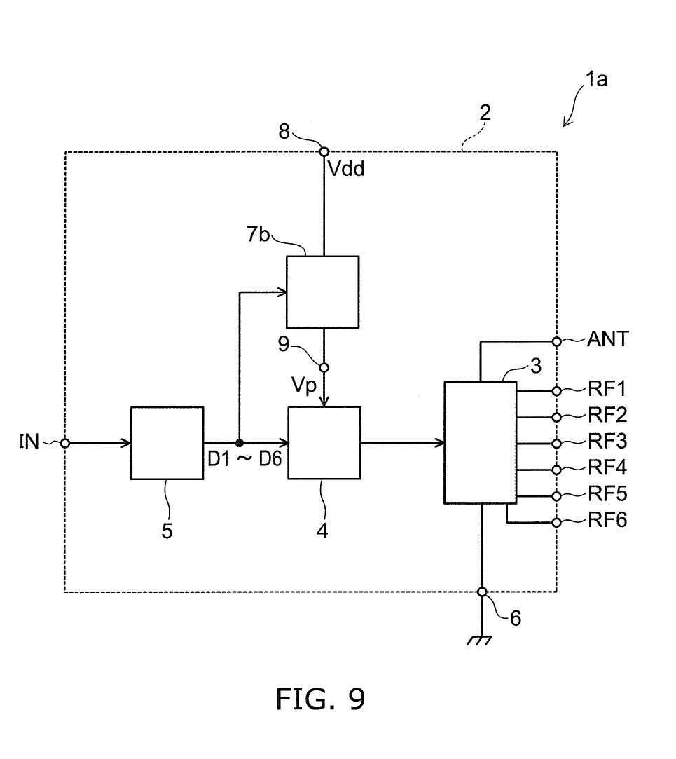

FIG. 9 is a circuit diagram illustrating a configuration of a semiconductor switch according to a second embodiment.

As shown in FIG. 9, a semiconductor switch 1a is configured with the power supply 7 of the semiconductor switch 1 replaced by a power supply 7b.

The power supply 7b receives input of signals D1 to D6 resulting from the decoding of a terminal switching signal IN by the interface circuit 5, and outputs the temperature controlled first potential Vp only when a port that requires predetermined second-order intermodulation distortion IMD2 characteristics, such as a UMTS port, is ON. Also, when a port for which particular characteristics are not required in the second-order intermodulation distortion IMD2, such as GSM format transmission and reception-use ports, is ON, the configuration is such that the first potential Vp is not temperature controlled.

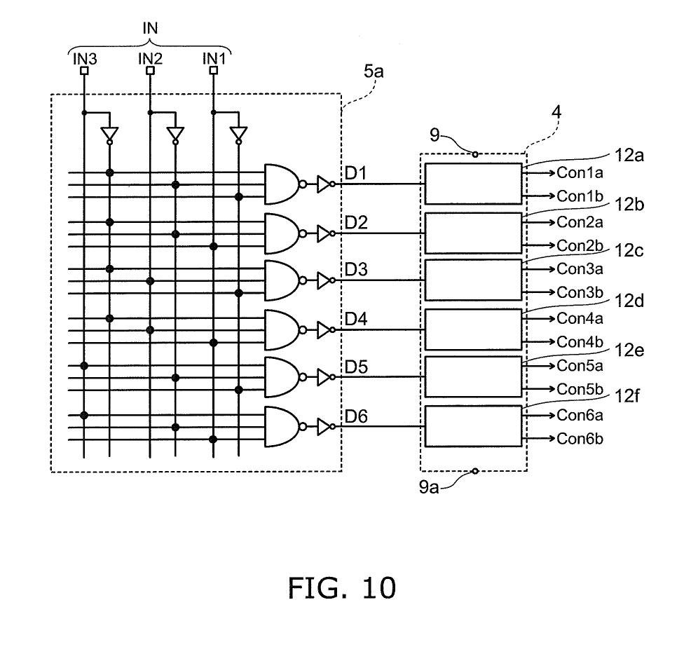

FIG. 10 is a circuit diagram illustrating a configuration of an interface circuit and a driver of the semiconductor switch.

As illustrated in FIG. 10, the interface circuit (surrounded by a broken line 5a) decodes the inputted terminal switching signal IN. The semiconductor switch 1a includes the SP6T switch section 3. Hence, the interface circuit 5a decodes a 3-bit terminal switching signal IN. Here the terminal switching signal IN is configured, starting from the LSB side, of three bits IN1, IN2 and IN3. Also, the interface circuit 5a outputs a 6-bit signal of D1 (LSB), D2, D3, D4, D5 and D6 (MSB).

When a 6-bit signal is inputted as the terminal switching signal IN, or there are two switch section 3 terminals, the interface circuit 5a is not required. Also, although a configuration in which the terminal switching signal IN is a parallel signal is illustrated in FIG. 4, the configuration may be the similar configuration in the case of a serial signal. Further, the power supply potential Vdd is supplied to the interface circuit 5a.

The signal decoded using the interface circuit 5a (decode signals) D1 to D6 are inputted to the driver (portion surrounded by broken line 4).

The driver 4 is configured using six level shift circuits 12a to 12f. As shown in FIG. 10, the high-potential power supply terminal 9 of the driver 4 is connected to the power supply 7b. The driver 4 is supplied with the first potential Vp via the high-potential power supply terminal 9. Also, the driver 4 is supplied with the second potential Vn via a low-potential power supply terminal 9a. As described above, the second potential Vn is the ground potential 0 V or a negative potential.

The level shift circuits 12a to 12f receives input of the decode signals D1 to D6, level-shift the high level to the first potential Vp and the low level to the second potential Vn, and outputs the results as control signals Con1a to Con6a and Con1b to Con 6b.

The level shift circuit 12a receives input of the signal D1 that is the LSB of the decode signals D1 to D6, and outputs the control signals Conga and Con1b. The level shift circuits 12b to 12f receive input of 1 bit of the decode signals D1 to D6 respectively, and output the control signals Con2a, Con2b to Con6a, and Con6b.

It is sufficient that the level shift circuit 12a level shifts decode signals D1 and D1−, for which the high level is the power supply potential Vdd and the low level is 0 V, to the control signals Con1a and Con1b, for which the high level is the power supply potential Vdd and the low level is the first potential Vn. The level shift circuit 12a need not have the configuration shown in FIG. 5 and may have a different configuration. The same applies to the level shift circuits 12b to 12f.

For example, a case in which radio-frequency terminals RF5 and RF6 are radio-frequency terminals, such as UMTS terminals, where predetermined characteristics are required in the second-order intermodulation distortion IMD2 will now be described. The radio-frequency terminals RF1 to RF4 are radio-frequency terminals, such as GSM terminals, which do not require particular characteristics in the second-order intermodulation distortion.

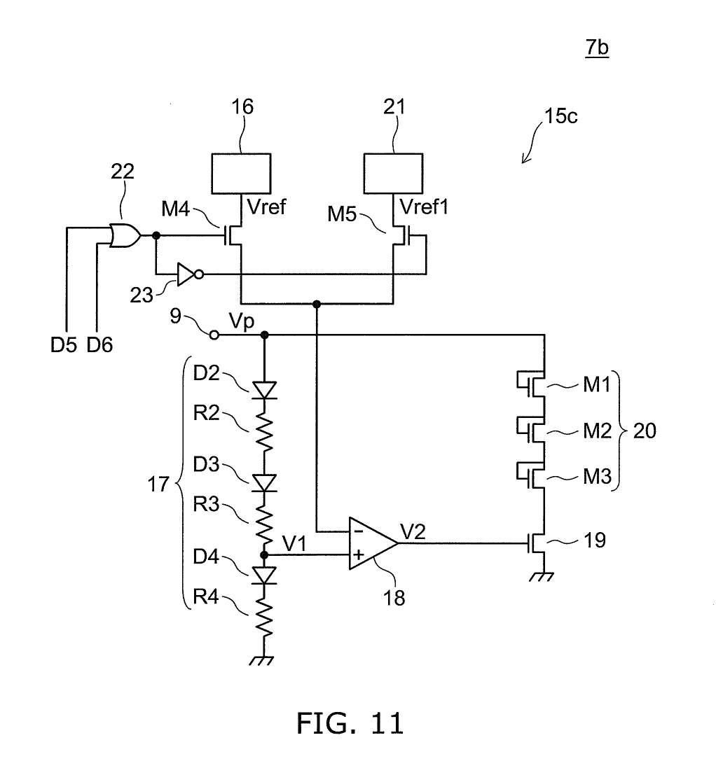

FIG. 11 is a circuit diagram illustrating a configuration of a clamper of the semiconductor switch.

In the clamper 15c shown in FIG. 11, a port detection circuit 22, an inverter circuit (INV) 23, a reference potential generator 21, and NMOS M4 and M5 have been added to the clamper 15a shown in FIG. 7.

When the terminal switching signal IN (IN1 to IN3) that sets a conduction state between (connects) the radio-frequency terminal RF5 or RF6 and the common terminal ANT is inputted to the interface circuit 5a, the high level is outputted as the decoded signal D5 or D6. The port detection circuit 22 is configured as a logical sum circuit (OR) and therefore outputs the high level when at least one of signal D5 and D6 is at the high level. Accordingly, when a UMTS format port is selected, the port detection circuit 22 outputs the high level.

The port detection circuit 22 operates using the power supply potential Vdd inputted from the power supply terminal 8 or an internal power supply potential Vdd1 (of 1.8 V, for example), which is the result of stabilizing the power supply potential Vdd. The high level potential outputted by the port detection circuit 22 is approximately the power supply potential Vdd or the internal power supply potential Vdd1. Although in FIG. 11 the port detection circuit 22 is configured as an OR, it is also possible to use a logical product circuit (NAND) and input the inverse of signals D5 and D6.

The power supply 7b includes a temperature control-type reference potential generator 16 and a non-temperature controlling reference potential generator 21. The temperature control-type reference potential generator 16 is the same as the reference potential generator 16 shown in FIG. 7 and generates a reference potential Vref having a positive temperature characteristic. The reference potential generator 21 is a voltage source circuit that is temperature-compensated to temperature coefficient 0, is configured using a band gap voltage source circuit or the like, and generates a reference potential Vref1.

The reference potential Vref is inputted to the inverting input terminal (−) of the operational amplifier 18 via the NMOS M4. Vref1 is inputted to the inverting input terminal (−) of the operational amplifier 18 via the NMOS M5.

The gate of the NMOS M4 is connected to the output of the port detection circuit 22, and the gate of the NMOS M5 is connected to the output of the port detection circuit 22 via the inverter circuit (INV) 23.

When the terminal switching signal IN (IN1 to IN3) that sets a connection state between the radio-frequency terminal RF5 or RF6 and the common terminal ANT is inputted, the port detection circuit 22 outputs the high level, the NMOS M4 goes ON and the NMOS M5 goes OFF.

Accordingly, when the UMTS format port is selected, the NMOS M4 is switched ON, and the reference potential Vref of the reference potential generator 16 is inputted to the inverting input terminal (−) of the operational amplifier 18. The clamper 15c operates in a similar manner to the clamper 15a shown in FIG. 7, clamping the first potential Vp to give a positive temperature characteristic.

Hence, in the case of UMTS format, increases in insertion loss can be suppressed, increases in the second-order intermodulation distortion IMD2 at low temperature can be suppressed, and the radio-frequency characteristics can thus be improved.

Also, when a port other than the UMTS format port is selected, the NMOS M5 is switched ON, and the reference potential Vref1 of the reference potential generator 21 is inputted to the inverting input terminal (−) of the operational amplifier 18. The clamper 15c clamps the first potential Vp to give a 0 temperature characteristic.

Hence, in the case of a GSM format other than the UMTS format, the first potential Vp is not temperature controlled and there is no risk that the insertion loss will worsen at low temperature.

Thus, the semiconductor switch according to the second embodiment changes the temperature characteristic of the first potential Vp according to the radio-frequency terminal connected based on the terminal switching signal IN. Hence, when a radio-frequency terminal that requires a predetermined characteristic for second-order intermodulation distortion IMD2 is selected, the first potential Vp is temperature controlled, increases in insertion loss can be suppressed, increases in the second-order intermodulation distortion IMD2 can be suppressed, and the radio-frequency characteristics can thus be improved.

The power supply 7b was described as being configured to include a temperature control-type reference potential generator 16 and a non-temperature controlling reference potential generator 21. However, a configuration using the clamper 15a shown in FIG. 6 is also possible.

Next, a third embodiment will be explained.

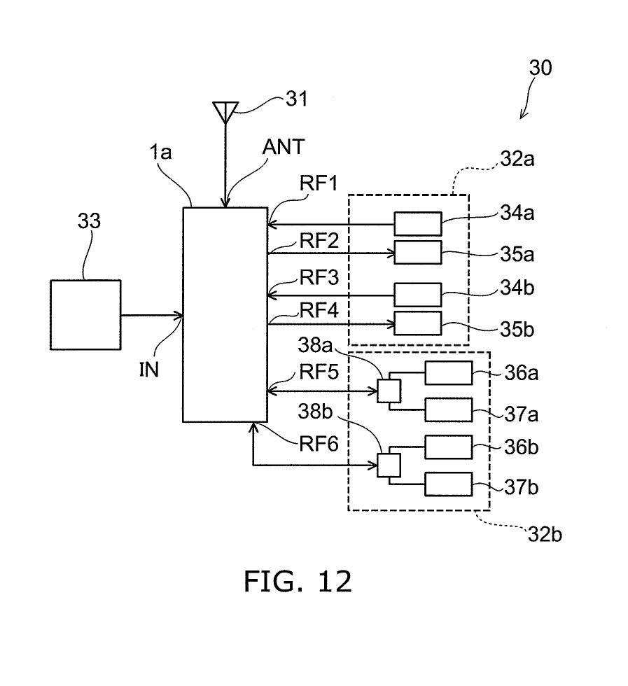

FIG. 12 is a block diagram illustrating a configuration of a wireless device according to a third embodiment.

As shown in FIG. 12, a wireless device 30 includes a semiconductor switch 1a, an antenna 31, transmission and receiving circuits 32a and 32b and a wireless controller 33.

The semiconductor switch 1a is similar to the semiconductor switch 1a shown in FIG. 8, and operates to switch connections between the common terminal ANT and the eight radio-frequency terminals RF1 to RF6 according to the terminal switching signal IN.

Also, as described above, in the semiconductor switch 1a, the decode signals D1 to D6 of the terminal switching signal IN are inputted to the power supply 7b. In the power supply 7b, the clamper 15c is used and the first potential Vp is temperature controlled when the terminal switching signal IN reaches a prescribed value of 5 or 6. Thus, when there is a conduction state between the common terminal ANT and the radio-frequency terminal RF5 or RF6, the worsening of the second-order intermodulation distortion IMD2 at low temperature is improved.

The common terminal ANT is connected to the antenna 31. The radio-frequency terminals RF1 to RF6 are connected to the transmission and receiving circuits 32a and 32b.

The antenna 31 transmits and receives radio-frequency signals in a band, such as 800 MHz to 2 GHz, corresponding to the wireless signals of mobile phones, such as GSM format or UMTS format signals.

The transmission and receiving circuit 32a includes transmitting circuits 34a and 34b, and receiving circuits 35a and 35b, and transmits and receives GSM format radio-frequency signals. The transmitting circuit 34a modulates a transmission signal formed from information such as audio signals, image signals, or binary data onto a GSM format radio-frequency signal and outputs the result to the radio-frequency terminal RF1 of the semiconductor switch 1a. The transmitting circuit 34b modulates the transmission signal onto a GSM format radio-frequency signal and outputs the result to the radio-frequency terminal RF2 of the semiconductor switch 1a.

The receiving circuit 35a receives a GSM format radio-frequency signal inputted from the radio-frequency terminal RF3, and demodulates to the reception signal formed from information such as an audio signal, image signal, or binary data. The receiving circuit 35b receives the GSM format radio-frequency signal from the radio-frequency terminal RF4 and demodulates to the reception signal.

The transmission and receiving circuit 32b includes transmitting circuits 36a and 36b, and receiving circuits 37a and 37b, duplexers 38a and 38b, and transmits and receives UMTS format radio-frequency signals.

The transmitting circuit 36a modulates a transmission signal onto a UMTS format radio-frequency signal and outputs the result to the radio-frequency terminal RF5 via the duplexer 38a. The receiving circuit 37a receives a UMTS format radio-frequency signal inputted from the radio-frequency terminal RF5 via the duplexer 38a, and demodulates to the reception signal.

The transmitting circuit 36b modulates a transmission signal onto a UMTS format radio-frequency signal and outputs the result to the radio-frequency terminal RF6 via the duplexer 38b. The receiving circuit 37b receives a UMTS format radio-frequency signal inputted from the radio-frequency terminal RF6 via the duplexer 38b, and demodulates to the reception signal.

The wireless controller 33 outputs the terminal switching signal IN to the semiconductor switch 1a to control connection between the terminals of the semiconductor switch 1a. The wireless controller 33 also controls the transmission and receiving circuits 32a and 32b. Thus the wireless controller 33 controls the transmitting circuits 34a, 34b, 36a and 36b and the receiving circuits 35a, 35b, 37a and 37b.

For example, when transmitting using the transmitting circuit 34a of the transmission and receiving circuit 32a, the wireless controller 33 outputs the terminal switching signal IN to the semiconductor switch 1a to connect the common terminal ANT with the radio-frequency terminal RF1 of the semiconductor switch 1a.

As described above, in the semiconductor switch 1a, when there is conduction state between the common terminal ANT and the radio-frequency terminals RF1 to RF4, the power supply 7b does not control the temperature characteristic of the first potential Vp. Hence, a high-power first potential Vp appropriated for GSM format is outputted and worsening of the insertion loss is suppressed.

Also in the semiconductor switch 1a, when there is conduction state between the common terminal ANT and the radio-frequency terminals RF5 and RF6, the temperature characteristic of the first potential Vp is controlled by the power supply 7b. Thus, the first potential Vp is temperature controlled to give insertion loss and second-order intermodulation distortion IMD2 characteristics suitable for UMTS format.

Hence, with the wireless device 30, increases in the insertion loss of the semiconductor switch 1a can be suppressed, increases in the second-order intermodulation distortion IMD2 due to temperature can be suppressed, and it is therefore possible to transmit each of GSM format and UMTS format radio-frequency signals from the antenna 31.

A configuration in which the semiconductor switch 1a for GSM format and UMTS format was described with reference to FIG. 12. It is to be noted, however, that another type of semiconductor switch 1 may be used. Also, other wireless communication formats may be used.

Moreover, in the wireless device 30 shown in FIG. 12, the modulation and demodulation are performed by the transmitting circuits 34a, 34b, 36a and 36b and the receiving circuits 35a, 35b, 37a and 37b, respectively. It is to be noted, however, that a configuration may be used whereby a common modulation and demodulation circuit is provided, the modulation signal is outputted to the transmitting circuit, and the signal inputted from the receiving circuit is demodulated.

Because the semiconductor switch according to the first or second embodiment is used in the manner described in the wireless device according to the third embodiment, increases in insertion loss can be suppressed, and increases in the second-order intermodulation distortion IMD2 due to temperature can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor switch comprising:
a switch section switching a connection between a common terminal and a plurality of radio-frequency terminals;
a driver outputting a control signal to the switch section based on a terminal switching signal; and
a power supply generating a first potential based on a reference potential varying in accordance with temperature and outputting the first potential to the driver.

2. The switch according to claim 1, wherein the switch section includes an SOI-structure MOSFET.

3. The switch according to claim 1, wherein the first potential has a positive temperature characteristic.

4. The switch according to claim 1, wherein the first potential has a negative temperature characteristic.

5. The switch according to claim 1, wherein the power supply changes the temperature characteristic of the first potential in accordance with a connecting the common terminal to each of the plurality of radio-frequency terminals.

6. The switch according to claim 1, wherein the power supply includes a clamper clamping the first potential to a potential varying in accordance with temperature.

7. The switch according to claim 6, wherein the clamper includes:
a first transistor connected between an output of the power supply and a ground terminal;
a reference potential generator generating a reference potential varying so as to provide a positive temperature characteristic;
a divider detecting the first potential; and
an amplifier comparing a potential detected by the divider with the reference potential and switching the first transistor ON or OFF.

8. The switch according to claim 7, wherein the divider includes a diode and a resistor connected in series.

9. The switch according to claim 7, wherein the clamper further includes a second transistor connected in series with the first transistor.

10. The switch according to claim 1, wherein the temperature characteristic of the reference potential generator has a positive temperature coefficient or a negative temperature coefficient in accordance with a temperature characteristic of second-order intermodulation distortion of the switch section.

11. A wireless device comprising:
an antenna;
a transmitting circuit modulating a transmission signal and transmitting a modulated signal via the antenna;
a receiving circuit demodulating a radio-frequency signal received via the antenna;
a semiconductor switch including:
a switch section switching a connection between a common terminal connected to the antenna and a plurality of radio-frequency terminals connected to the transmitting circuit and the receiving circuit;
a driver outputting a control signal to the switch section based on a terminal switching signal; and
a power supply generating a first potential based on a reference potential varying in accordance with temperature and outputting the first potential to the driver; and
a wireless controller outputting the terminal switching signal to the semiconductor switch.

12. The device according to claim 11, wherein the switch section includes an SOI-structure MOSFET.

13. The device according to claim 11, wherein the first potential has a positive temperature characteristic.

14. The device according to claim 11, wherein the first potential has a negative temperature characteristic.

15. The device according to claim 11, wherein the power supply changes the temperature characteristic of the first potential in accordance with a connecting the common terminal to each of the plurality of radio-frequency terminals.

16. The device according to claim 11, wherein the power supply includes a clamper clamping the first potential to a potential varying in accordance with temperature.

17. The device according to claim 16, wherein in the clamper includes:
a first transistor connected between an output of the power supply and a ground terminal;
a reference potential generator generating a reference potential varying so as to provide a positive temperature characteristic;
a divider detecting the first potential; and
an amplifier comparing a potential detected by the divider with the reference potential and switching the first transistor ON or OFF.

18. The device according to claim 17, wherein the divider includes a diode and a resistor connected in series.

19. The device according to claim 17, wherein the clamper further includes a second transistor connected in series with the first transistor.

20. The device according to claim 11, wherein the temperature characteristic of the reference potential generator has a positive temperature coefficient or a negative temperature coefficient according to a temperature characteristic of second-order intermodulation distortion of the switch section.
